(19) United States
(12) Patent Application Publication
(10) Pub. No.: US 2005/0268204 A1
(43) Pub. Date: Dec. 1, 2005

(54) Decoding apparatus and decoding circuit

(75) Inventor: Kohsuke Harada, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/138,999

(22) Filed: May 27, 2005

(30) Foreign Application Priority Data
May 31, 2004 (JP) 2004-162418

(51) Int. Cl. H03M 13/00; H03M 13/03

(52) U.S. Cl. 714/758

(57) ABSTRACT

A detecting unit detects an input signal and acquires likelihood values of respective binary data items included in the data. On the basis of reliabilities of the likelihood values of the respective binary data items acquired by the detecting unit, a scheduling unit draws up an operation schedule to execute an LDPC operation using the likelihood values of higher reliabilities with priority. On the basis of the operation schedule, an LDPC decoding unit executes decoding by executing the LDPC operation using the likelihood values acquired by the detecting unit.

### CROSS-REFERENCE TO RELATED APPLICATIONS

This application is based upon and claims the benefit of priority from prior Japanese Patent Application No. 2004-162418, filed May 31, 2004, the entire contents of which are incorporated herein by reference.

### BACKGROUND OF THE INVENTION

1. Field of the Invention

This invention relates to a decoding apparatus and a decoding circuit using an LDPC (Low Density Parity Check) code employed in, for example, a communications system, information input/output system and the like.

2. Description of the Related Art

As is generally known, a bit sequence encoded with an LDPC code, i.e. a low density parity check code has a characteristic that an error-correcting capability is varied by the order of a variable node of a check matrix used by an encoder.

In a conventional decoding apparatus using a LDPC code, particularly, a decoding apparatus corresponding to a multivalued modulation scheme, bits of the bit sequence encoded with the LDPC code are assigned at random to signal points of multivalued modulation or sequentially assigned directly thereto to execute decoding, without considering the order of the variable node, i.e. the error-correcting capability to each bit.

It is known that in the multivalued modulation, reliability of the decoding apparatus can be improved by optimally assigning the bits of the bit sequence to the signal points while considering the order of the variable node of the check matrix (see, for example, Capacity-approaching bandwidth-efficient coded modulation scheme based on low-density parity check code (IEEE Transaction on Information Theory, Vol. 49, No. 9, September 2003)).

In addition, the decoding apparatus using the LDPC code needs to repeat the decoding, having a problem that the amount of the decoding is increased and much time needs to be spent for the decoding. The decoding apparatus is unsuitable for the high-speed communications system. For this reason, to make the decoding apparatus applicable for the communications system, it is requested that the amount of decoding should be reduced without damaging the reliability of the system.

Incidentally, in the conventional decoding using the LDPC code, a posteriori probability value of the information bit sequence to be decoded is converged by simultaneously executing operations of all the likelihood values of variable nodes and check nodes of the check matrix. To accelerate the convergence of the posteriori probability value, a method of serially executing parts of the operations of the variable nodes and check nodes is proposed (see, for example, A new schedule for decoding low-density parity-check codes (IEEE GLOBECOM2001)).

This method is effective if the modulation scheme is binary. In the communications system employing the multivalued modulation, however, the convergence of the posteriori probability value cannot be effectively accelerated by this method.

Examples of the modulation scheme employed here as the multivalued modulation are: M-value PSK (Phase Shift Keying), M-value QAM (Quadrature Amplitude Modulation), M-value ASK (Amplitude Shift Keying), M-value AMPM (Amplitude Modulation-Phase Modulation), M-value PPM (Pulse Position Modulation), OFDM (Orthogonal Frequency Division Multiplexing), CDMA (Code Division Multiple Access), and the like.

The conventional decoding apparatus, using the LDPC code, has a problem that much time is required for the decoding since the amount of the decoding is increased.

### BRIEF SUMMARY OF THE INVENTION

The present invention has been accomplished to solve the above-described problems. The object of the present invention is to provide a decoding apparatus and a decoding circuit capable of effectively executing decoding without degrading the decoding characteristics.

According to an aspect of the present invention, there is provided a decoding apparatus of decoding encoded data with an LDPC code. The apparatus comprises a detecting unit configured to detect an input signal including binary encoded data to acquire a likelihood value of each binary data item of a plurality of binary data items of the binary encoded data for obtaining a plurality of likelihood values which differ in reliability to one another, a schedule drawing unit configured to draw up an operation schedule to execute an arithmetic operation for decoding using with priority the likelihood value of higher reliability, in accordance with the reliability of the likelihood value of the each binary data item, and a decoding unit configured to decode the encoded data by executing the operation using the likelihood value acquired by the detecting unit, in accordance with the operation schedule.

### BRIEF DESCRIPTION OF THE SEVERAL VIEWS OF THE DRAWING

FIG. 1 is a block diagram showing a communications system according to a first embodiment of the present invention;

FIG. 2 is an illustration showing reliability of signal points of 8PSK modulation;

FIG. 3 is an illustration showing an idea of a decoding operation executed by an LDPC decoding unit of a receiving apparatus shown in FIG. 1;

FIG. 4 is a table showing the idea of a decoding operation executed by an LDPC decoding unit of a receiving apparatus shown in FIG. 1;

FIG. 5 is a block diagram showing a receiving apparatus according to a second embodiment of the present invention;

FIG. 6 is a graph showing a condition that reliability of a bit sequence is varied in accordance with reception quality;

FIG. 7 is an illustration showing an idea of a decoding operation executed by an LDPC decoding unit of a receiving apparatus shown in FIG. 5;

FIG. 8 is a table showing the idea of a decoding operation executed by an LDPC decoding unit of a receiving apparatus shown in FIG. 5;

FIG. 9 is a block diagram showing a communications system according to a third embodiment of the present invention;

FIG. 10 is an illustration showing an idea of a decoding operation executed by an LDPC decoding unit of a receiving apparatus shown in FIG. 9;

FIG. 11 is a table showing the idea of a decoding operation executed by an LDPC decoding unit of a receiving apparatus shown in FIG. 9; and

FIG. 12 is a block diagram showing a receiving apparatus according to a fourth embodiment of the present invention.

### DETAILED DESCRIPTION OF THE INVENTION

Embodiments of the present invention will be explained below with reference to the accompanying drawings. In the following descriptions, a decoding circuit according to the present invention is applied to a decoding apparatus provided in a receiving apparatus of a communications system.

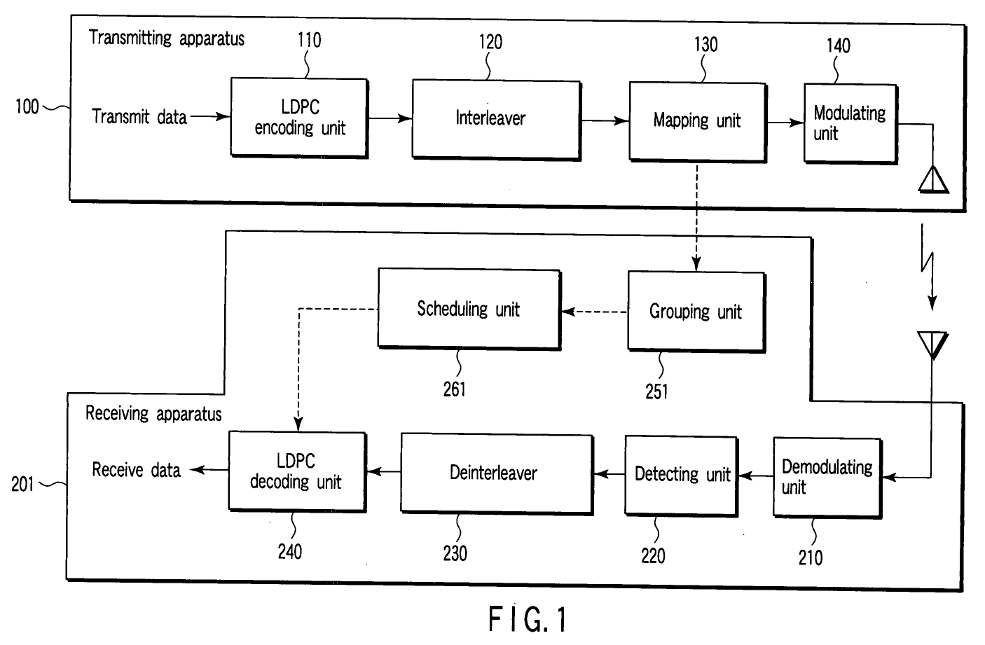

FIG. 1 is a block diagram showing a communications system according to a first embodiment of the present invention. The communications system comprises a transmitting apparatus 100 and a receiving apparatus 201. The transmitting apparatus 100 encodes transmit data with an LDPC (Low Density Parity Check) code and executes a radio transmission of the encoded data. The receiving apparatus 201 receives and decodes the data transmitted from the transmitting apparatus 100 to acquire the receive data.

The transmitting apparatus 100 comprises an LDPC encoding unit 110, an interleaver 120, a mapping unit 130 and a modulating unit 140. The LDPC encoding unit 110 encodes the transmit data with the LDPC code and outputs the encoded bit sequence. The bit sequence is interleaved in bits by the interleaver 120 and output to the mapping unit 130.

The mapping unit 130 executes labeling to split the bit sequence interleaved by the interleaver 120, into bit sequences of the unit that corresponds to a modulation scheme to be employed by the modulating unit 140 of a subsequent processing, and then executes mapping to make the labeled bit sequences correspond to signal points of the modulation scheme. Examples of the labels used here are a gray label, set partitioning, a random label and the like.

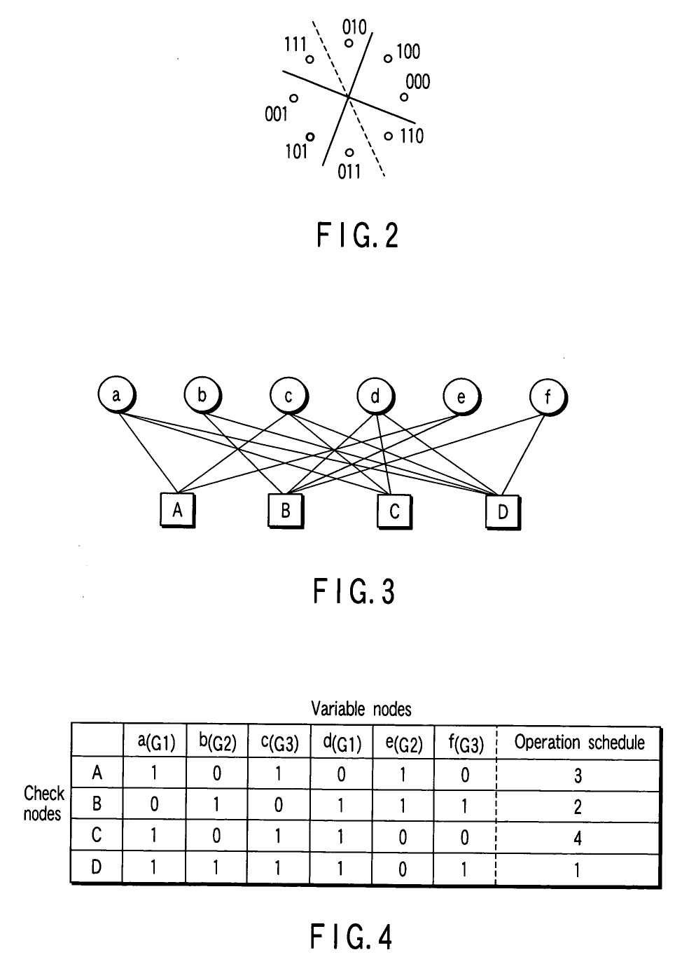

For example, the modulating unit 140 executes multivalued modulation in the 8PSK (Phase Shift Keying) that has a signal point distribution as shown in FIG. 2. Since the modulation scheme employed by the modulating unit 140 is 8PSK, the mapping unit 130 executes labeling which splits the bit sequence interleaved by the interleaver 120 into three-bit bit sequences.

After that, the mapping unit 130 executes mapping which makes the three-bit bit sequences split by the labeling correspond to any signal point of the 8PSK in accordance with the contents of the bit sequences, and outputs a result of the mapping to the modulating unit 140. The modulating unit 140 processes a carrier by the multivalued modulation using the processing result of the mapping unit 130 and irradiates the carrier into space via an antenna.

The receiving apparatus 201 comprises a demodulating unit 210, a detecting unit 220, a deinterleaver 230, an LDPC decoding unit 240, a grouping unit 251 and a scheduling unit 261. The demodulating unit 210 receives the radio signal transmitted from the transmitting apparatus 100 via an antenna and demodulates the received signal in the 8PSK.

The detecting unit 220 detects a demodulation result of the demodulating unit 210 and acquires a likelihood value of each bit in the bit sequence of the interleaved state. The likelihood value of each bit is deinterleaved by the deinterleaver 230 and output to the LDPC decoding unit 240. The deinterleaver 230 corresponds to the interleaving of the interleaver 120 of the transmitting apparatus 100.

The grouping unit 251 groups variable nodes of the LDPC decoding unit 240 in response to the labeling and mapping of the mapping unit 130. The mapping unit 130 executes the labeling and mapping in the 8PSK that is employed by the modulating unit 140. In the 8PSK modulation, 3-bit information can be transmitted for each symbol.

The bit data items of three bits are different in reliability from each other as shown in FIG. 2. The data items of the first bit are definitely different from those of the adjacent signal points, and there is a high possibility that the data items will cause an error. Thus, the data items are said to have lower reliabilities. The data items of the third bit are common to those of the signal points in each of two ranges divided by a broken line, and there is a low possibility that the data items will cause an error. Thus, the data items are said to have higher reliabilities. The data items of the second bit are common to those of the signal points in each of four ranges divided by solid lines, and there is a lower possibility that the data items will cause an error as compared with the data items of the first bit. However, there is a higher possibility that the data items will cause an error as compared with the data items of the third bit.

The LDPC decoding unit 240 has a structure corresponding to the encoding of the transmitting apparatus 100, and executes LDPC decoding by using variable nodes a, b, c, d, e, f and check nodes A, B, C, D. Correspondence of these nodes is determined on the basis of the decoding (encoding) algorithm. It is assumed here that the correspondence is determined as shown in FIG. 3. In this case, the likelihood values of two symbols or six bits are assigned to corresponding variable nodes a, b, c, d, e, f. The variable nodes a, b, c, d, e, f retain the assigned likelihood values.

The likelihood value of the first bit, of one of two symbols, is retained by the variable node a, the likelihood value of the second bit is retained by the variable node b, and the likelihood value of the third bit is retained by the variable node c. The likelihood value of the first bit, of the other symbol, is retained by the variable node d, the likelihood value of the second bit is retained by the variable node e, and the likelihood value of the third bit is retained by the variable node f.

In this case, the grouping unit 251 classifies the variable nodes a and d into group G1 since they retain the likelihood values of the same reliabilities. Similarly, the grouping unit 251 classifies the variable nodes b and e into group G2 since they retain the likelihood values of the same reliabilities. The grouping unit 251 classifies the variable nodes c and f into group G3 since they retain the likelihood values of the same reliabilities.

The scheduling unit 261 draws up an operation schedule to execute an operation of the check node using many variable nodes retaining the likelihood values of higher reliabilities, with priority, on the basis of the result of grouping executed by the grouping unit 251 and the correspondence between the variable nodes and the check nodes shown in FIG. 3.

The variable nodes and the check nodes of the LDPC decoding unit 240 correspond as shown in FIG. 3. Thus, the scheduling unit 261 draws up the operation schedule as shown in FIG. 4. In this figure, “1” represents the correspondence between the variable nodes and the check nodes while “0” represents no correspondence there between.

In other words, the operation schedule of FIG. 4 is drawn, such that the check node corresponding to many variable nodes of group G3 retaining the likelihood values of higher reliabilities is calculated with priority while the check node corresponding to many variable nodes of group G1 retaining the likelihood values of lower reliabilities is calculated without priority.

The LDPC decoding unit 240 executes an LDPC decoding operation using the variable nodes and check nodes on the basis of the operation schedule drawn up by the scheduling unit 261. Thus, the LDPC decoding unit 240 acquires probability values of the respective bits of the receive data, executes hard decision about the acquired probability values and obtains the receive data. The LDPC decoding operation is explained below with reference to the operation schedule of FIG. 4.

By using the check node D which is the first place in the order of the operation schedule, the LDPC decoding unit 240 executes the operation on the basis of the likelihood values retained by the variable nodes a, b, c, d, f corresponding to the check node, and the operation result is retained by the check node D. By using the variable nodes a, b, c, d, f concerning the check node D, the LDPC decoding unit 240 executes the operation on the basis of likelihood values retained by the check nodes corresponding to each of the variable nodes, and updates the likelihood values retained by the variable nodes a, b, c, d, f on the basis of the operation result.

After that, by using the check node B which is the second place in the order of the operation schedule, the LDPC decoding unit 240 executes the operation on the basis of the likelihood values retained by the variable nodes b, d, e, f corresponding to the check node, and the operation result is retained by the check node B. By using the variable nodes b, d, e, f concerning the check node B, the LDPC decoding unit 240 executes the operation on the basis of likelihood values retained by the check nodes corresponding to each of the variable nodes, and updates the likelihood values retained by the variable nodes b, d, e, f on the basis of the operation result.

After that, by using the check node A which is the third place in the order of the operation schedule, the LDPC decoding unit 240 executes the operation on the basis of the likelihood values retained by the variable nodes a, c, e corresponding to the check node, and the operation result is retained by the check node A. By using the variable nodes a, c, e concerning the check node A, the LDPC decoding unit 240 executes the operation on the basis of likelihood values retained by the check nodes corresponding to each of the variable nodes, and updates the likelihood values retained by the variable nodes a, c, e on the basis of the operation result.

Finally, by using the check node C which is the fourth place in the order of the operation schedule, the LDPC decoding unit 240 executes the operation on the basis of the likelihood values retained by the variable nodes a, c, d corresponding to the check node, and the operation result is retained by the check node C. By using the variable nodes a, c, d concerning the check node C, the LDPC decoding unit 240 executes the operation on the basis of likelihood values retained by the check nodes corresponding to each of the variable nodes, and updates the likelihood values retained by the variable nodes a, c, d on the basis of the operation result.

The LDPC decoding unit 240, for example, repeats the LDPC decoding operation based on the above-described operation schedule at a preset number of times, recognizes the likelihood values finally retained by the variable nodes a, b, c, d, e, f as posteriori probability values, executes hard decision of the posteriori probability values and acquires the receive data. Besides setting the number of times of the repeated operation, the repeated operation may be stopped when the parity of the operation result is checked and a syndrome becomes “0”.

In addition, to detect the reliability of the likelihood of each variable node at the start of decoding, the LDPC decoding unit 240 may have a further step of executing an operation based on the likelihood values retained by the variable nodes a, b, c, d, e, f by using all of the check nodes A, B, C, D, making the check nodes A, B, C, D retain the operation result, using all of the variable nodes a, b, c, d, e, f and executing an operation based on the likelihood values of the check nodes corresponding to each of the variable nodes, and updating the likelihood values retained by the variable nodes a, b, c, d, e, f on the basis of the operation result.

In the receiving apparatus 201 having the above-described structure, it is noticed that the likelihood values of the bit sequences included in one symbol are different in reliability by bit when the multivalued modulation is executed, as shown in FIG. 2. The grouping unit 251 classifies the variable nodes of the LDPC decoding unit 240 into groups in accordance with the reliabilities.

The scheduling unit 261 preliminarily draws up an operation schedule to execute an operation of the check node using many variable nodes retaining the likelihood values of higher reliabilities, with priority, on the basis of the result of grouping executed by the grouping unit 251 and the correspondence between the variable nodes and the check nodes used in the LDPC decoding operation of the LDPC decoding unit 240. The LDPC decoding unit 240 executes the LDPC decoding operation on the basis of the operation schedule.

According to the receiving apparatus 201 having the above-described structure, an operation of the check node using many variable nodes retaining the likelihood values of higher reliabilities, of the LDPC decoding operation, is executed with priority. The posteriori probability values can be therefore converged quickly during the repeated operation using the variable nodes and the check nodes. For this reason, even if the multivalued modulation is employed as the modulation scheme, the posteriori probability values can be efficiently converged without degrading the decoding characteristics.

In the present embodiment, the scheduling unit 261 draws up an operation schedule to execute an operation of the check node using many variable nodes retaining the likelihood values of higher reliabilities, with priority, on the basis of the result of grouping executed by the grouping unit 251 and the correspondence between the variable nodes and the check nodes used in the LDPC decoding operation of the LDPC decoding unit 240.

On the other hand, the grouping and the correspondence of the nodes have been known prior to executing the communications. Therefore, even if the receiving apparatus 201 does not comprise the grouping unit 251 and the scheduling unit 261, the preliminarily drawn operation schedule can be set in the LDPC decoding unit 240. On the basis of the grouping and the correspondence of the nodes, the operation schedule can be dynamically changed by the grouping unit 251 and the scheduling unit 261.

In addition, the scheduling unit 261 draws up the operation schedule of the check nodes and the LDPC decoding unit 240 executes the LDPC decoding operation on the basis of the operation schedule, as shown in FIG. 4. Instead of this, for example, the scheduling unit 261 may draw up the operation schedule to execute the operation using the variable nodes of the group retaining the likelihood values of the highest reliabilities with priority.

In the case of FIG. 3, for example, after the LDPC decoding operation using the variable nodes and the check nodes is executed, the operation using the variable nodes c, f of group G3 retaining the likelihood values of the highest reliabilities is executed. On the basis of the operation result, the operation using the check nodes A, B, C, D is executed. After that, the operation using the variable nodes b, e of group G2 retaining the likelihood values of the second highest reliabilities is executed and, on the basis of the operation result, the operation using the check nodes A, B, C, D is executed. Furthermore, the operation using the variable nodes a, d of group G1 retaining the likelihood values of lower reliabilities is executed and, on the basis of the operation result, the operation using the check nodes A, B, C, D is executed.

According to such an operation schedule, too, the posteriori probability values can be converged quickly during the repeated operation using the variable nodes and the check nodes. Even if the multivalued modulation is employed as the modulation scheme, the posteriori probability values can be efficiently converged without degrading the decoding characteristics.

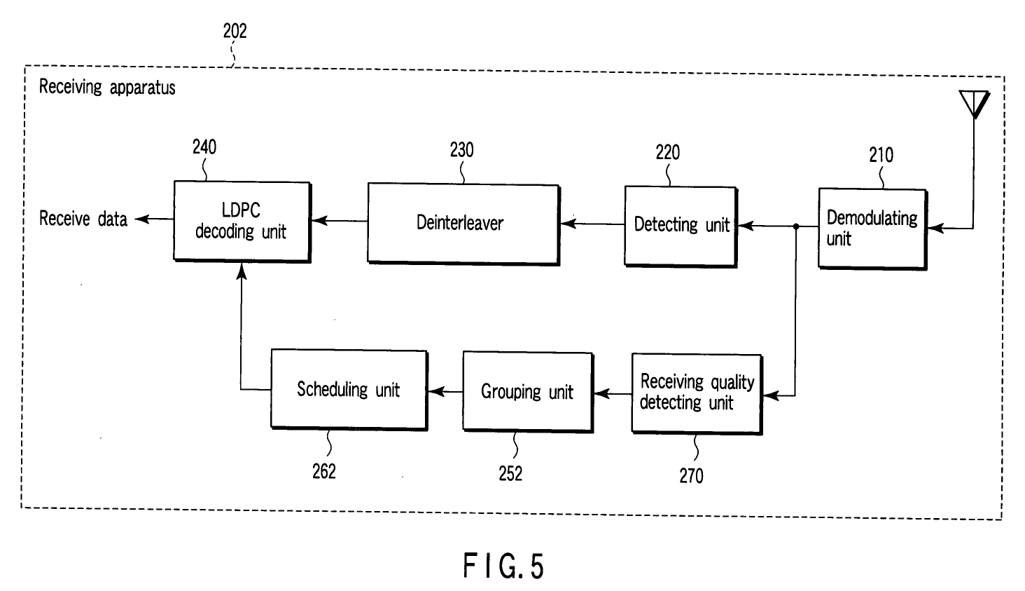

Next, a receiving apparatus 202 according to a second embodiment of the present invention will be explained. FIG. 5 shows a structure of the receiving apparatus. The receiving apparatus 202 receives the data transmitted from the transmitting apparatus 100 shown in FIG. 1, and decodes the data to acquire the receive data.

The receiving apparatus 202 comprises a demodulating unit 210, a detecting unit 220, a deinterleaver 230, an LDPC decoding unit 240, a grouping unit 252, a scheduling unit 262, and a receiving quality detecting unit 270. The demodulating unit 210 receives the radio signal transmitted from the transmitting apparatus 100 via an antenna and demodulates the received radio signal in the 8PSK.

The detecting unit 220 detects the demodulation result of the demodulating unit 210 and acquires the likelihood value of each bit in the bit sequence in the interleaved state. The likelihood value of each bit is deinterleaved by the deinterleaver 230 and output to the LDPC decoding unit 240. The deinterleaver 230 corresponds to the interleaving of the interleaver 120 of the transmitting apparatus 100.

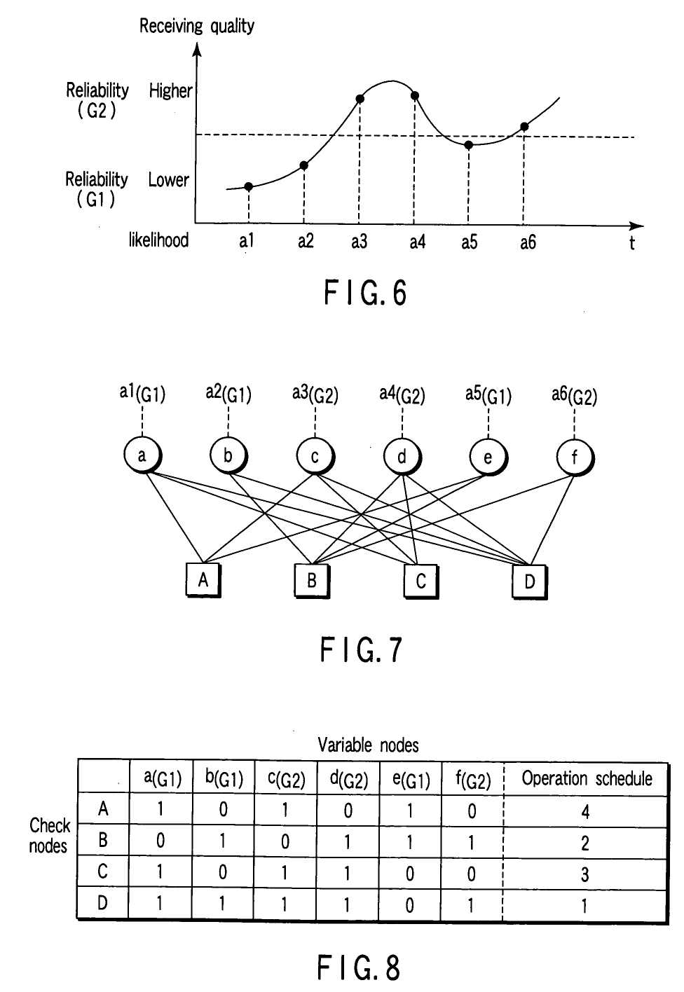

The receiving quality detecting unit 270 detects receiving quality of the signal from which the likelihood value required by the detecting unit 220 is obtained, from the demodulation result of the demodulating unit 210, and acquires the reliability of the likelihood value from the detection result as shown in FIG. 6.

The grouping unit 252 dynamically groups the variable nodes of the LDPC decoding unit 240 in accordance with the reliability acquired by the receiving quality detecting unit 270. The grouping unit 252 classifies the variable nodes to which likelihood values of lower reliabilities are assigned, into group G1 while it classifies the variable nodes to which likelihood values of higher reliabilities are assigned, into group G2.

The LDPC decoding unit 240 has a structure corresponding to the encoding of the LDPC encoding unit 110 and executes LDPC decoding by using variable nodes a, b, c, d, e, f and check nodes A, B, C, D. Correspondence of these nodes is determined on the basis of the decoding (encoding) algorithm. It is assumed here that the correspondence is determined as shown in FIG. 7. In addition, it is assumed that reliabilities of the likelihood values assigned to the variable nodes a, b, c, d, e, f are a1, a2, a3, a4, a5, a6 in FIG. 7.

In this case, the grouping unit 252 classifies the variable nodes a, b, e into group G1 since the variable nodes a, b, e retain the likelihood values of lower reliabilities. Similarly, the grouping unit 252 classifies the variable nodes c, d, f into group G2 since the variable nodes c, d, f retain the likelihood values of lower reliabilities.

The scheduling unit 262 draws up an operation schedule to execute an operation of the check node using many variable nodes retaining the likelihood values of higher reliabilities, with priority, on the basis of the result of grouping executed by the grouping unit 252 and the correspondence between the variable nodes and the check nodes shown in FIG. 7.

The variable nodes and the check nodes of the LDPC decoding unit 240 correspond as shown in FIG. 7. Thus, the scheduling unit 262 draws up the operation schedule as shown in FIG. 8. In this figure, “1” represents the correspondence between the variable nodes and the check nodes while “0” represents no correspondence there between.

In other words, the operation schedule of FIG. 8 is drawn such that the check node corresponding to many variable nodes of group G2 retaining the likelihood values of higher reliabilities is calculated with priority while the check node corresponding to many variable nodes of group G1 retaining the likelihood values of lower reliabilities is calculated without priority.

The LDPC decoding unit 240 executes an LDPC decoding operation using the variable nodes and check nodes on the basis of the operation schedule drawn up by the scheduling unit 262. Thus, the LDPC decoding unit 240 acquires probability values of the respective bits of the receive data, executes hard decision about the acquired probability values and obtains the receive data. The LDPC decoding operation is explained below with reference to the operation schedule of FIG. 8.

By using the check node D which is the first place in the order of the operation schedule, the LDPC decoding unit 240 executes the operation on the basis of the likelihood values retained by the variable nodes a, b, c, d, f corresponding to the check node, and the operation result is retained by the check node D. By using the variable nodes a, b, c, d, f concerning the check node D, the LDPC decoding unit 240 executes the operation on the basis of likelihood values retained by the check nodes corresponding to each of the variable nodes, and updates the likelihood values retained by the variable nodes a, b, c, d, f on the basis of the operation result.

After that, by using the check node B which is the second place in the order of the operation schedule, the LDPC decoding unit 240 executes the operation on the basis of the likelihood values retained by the variable nodes b, d, e, f corresponding to the check node, and the operation result is retained by the check node B. By using the variable nodes b, d, e, f concerning the check node B, the LDPC decoding unit 240 executes the operation on the basis of likelihood values retained by the check nodes corresponding to each of the variable nodes, and updates the likelihood values retained by the variable nodes b, d, e, f on the basis of the operation result.

After that, by using the check node C which is the third place in the order of the operation schedule, the LDPC decoding unit 240 executes the operation on the basis of the likelihood values retained by the variable nodes a, c, d corresponding to the check node, and the operation result is retained by the check node C. By using the variable nodes a, c, d concerning the check node C, the LDPC decoding unit 240 executes the operation on the basis of likelihood values retained by the check nodes corresponding to each of the variable nodes, and updates the likelihood values retained by the variable nodes a, c, d on the basis of the operation result.

Finally, by using the check node A which is the fourth place in the order of the operation schedule, the LDPC decoding unit 240 executes the operation on the basis of the likelihood values retained by the variable nodes a, c, e corresponding to the check node, and the operation result is retained by the check node A. By using the variable nodes a, c, e concerning the check node A, the LDPC decoding unit 240 executes the operation on the basis of likelihood values retained by the check nodes corresponding to each of the variable nodes, and updates the likelihood values retained by the variable nodes a, c, e on the basis of the operation result.

The LDPC decoding unit 240, for example, repeats the LDPC decoding operation based on the above-described operation schedule at a preset number of times, recognizes the likelihood values finally retained by the variable nodes a, b, c, d, e, f as posteriori probability values, executes hard decision of the posteriori probability values and acquires the receive data. Besides setting the number of times of the repeated operation, the repeated operation may be stopped when the parity of the operation result is checked and a syndrome becomes “0”.

In addition, to detect the reliability of the likelihood of each variable node at the start of decoding, the LDPC decoding unit 240 may have a further step of executing an operation based on the likelihood values retained by the variable nodes a, b, c, d, e, f by using all of the check nodes A, B, C, D, making the check nodes A, B, C, D retain the operation result, using all of the variable nodes a, b, c, d, e, f and executing an operation based on the likelihood values of the check nodes corresponding to each of the variable nodes, and updating the likelihood values retained by the variable nodes a, b, c, d, e, f on the basis of the operation result.

In the receiving apparatus 202 having the above-described structure, it is noticed that the reliabilities of the likelihood values detected by the detecting unit 220 are varied in accordance with the receiving quality. The receiving quality detecting unit 270 acquires the reliabilities of the likelihood values detected by the detecting unit 220 and, on the basis of the reliabilities, the grouping unit 252 classifies the variable nodes of the LDPC decoding unit 240 into groups.

The scheduling unit 262 dynamically draws up an operation schedule to execute an operation of the check node using many variable nodes retaining the likelihood values of higher reliabilities, with priority, on the basis of the result of grouping executed by the grouping unit 252 and the correspondence between the variable nodes and the check nodes used in the LDPC decoding operation of the LDPC decoding unit 240. The LDPC decoding unit 240 executes the LDPC decoding operation on the basis of the operation schedule.

According to the receiving apparatus 202 having the above-described structure, an operation of the check node using many variable nodes retaining the likelihood values of higher reliabilities, of the LDPC decoding operation, is executed with priority. The posteriori probability values can be therefore converged quickly during the repeated operation using the variable nodes and the check nodes. For this reason, even if the multivalued modulation is employed as the modulation scheme, the posteriori probability values can be efficiently converged without degrading the decoding characteristics.

In the above-described embodiment, the scheduling unit 262 draws up the operation schedule of the check nodes and the LDPC decoding unit 240 executes the LDPC decoding operation on the basis of the operation schedule, as shown in FIG. 8. Instead of this, for example, the scheduling unit 262 may draw up the operation schedule to execute the operation using the variable nodes of the group retaining the likelihood values of the highest reliabilities with priority.

In the case of FIG. 7, for example, after the LDPC decoding operation using the variable nodes and the check nodes is executed, the operation using the variable nodes c, d, f of group G2 retaining the likelihood values of the higher reliabilities is executed. On the basis of the operation result, the operation using the check nodes A, B, C, D is executed. After that, the operation using the variable nodes a, b, e of group G1 retaining the likelihood values of the lower reliabilities is executed and, on the basis of the operation result, the operation using the check nodes A, B, C, D is executed.

According to such an operation schedule, too, the posteriori probability values can be converged quickly during the repeated operation using the variable nodes and the check nodes. Even if the multivalued modulation is employed as the modulation scheme, the posteriori probability values can be efficiently converged without degrading the decoding characteristics.

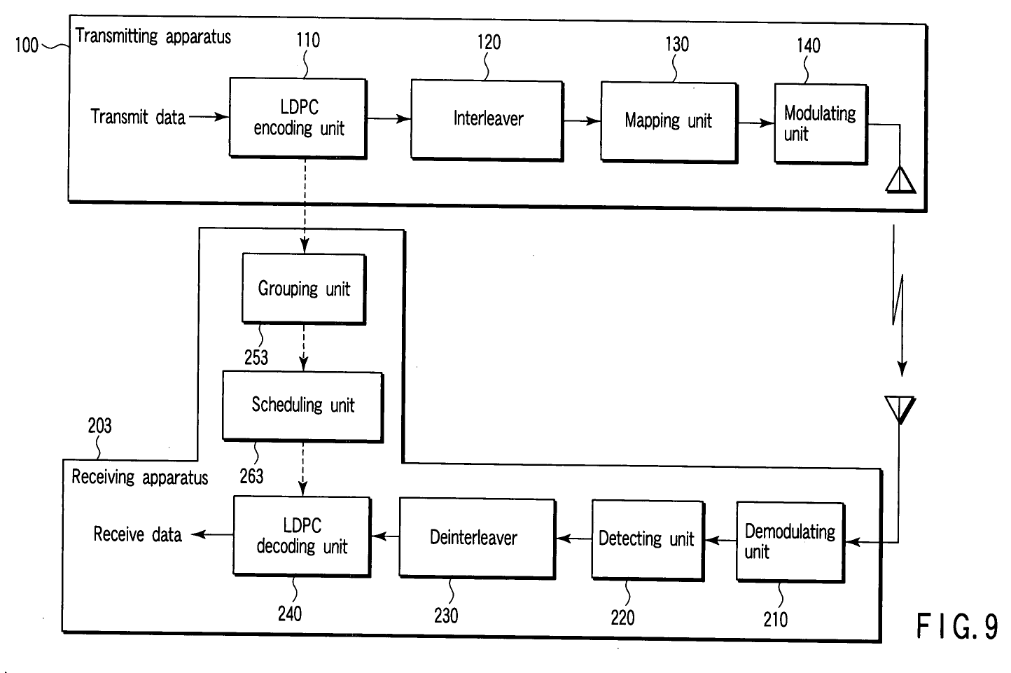

FIG. 9 is a block diagram showing a communications system according to a third embodiment of the present invention. The communications system comprises a transmitting apparatus 100 and a receiving apparatus 203. The transmitting apparatus 100 encodes transmit data with an LDPC code and executes a radio transmission of the encoded data. The receiving apparatus 203 receives and decodes the data transmitted from the transmitting apparatus 100 to acquire the receive data.

The transmitting apparatus 100 comprises an LDPC encoding unit 110, an interleaver 120, a mapping unit 130 and a modulating unit 140. The LDPC encoding unit 110 encodes the transmit data with the LDPC code and outputs the encoded bit sequence. The bit sequence is interleaved in bits by the interleaver 120 and output to the mapping unit 130.

The mapping unit 130 executes labeling to split the bit sequence interleaved by the interleaver 120, into bit sequences of the unit that corresponds to a modulation scheme to be employed by the modulating unit 140 of a subsequent processing, and then executes mapping to make the labeled bit sequences correspond to signal points of the modulation scheme. Examples of the labels used here are a gray label, set partitioning, a random label and the like.

For example, the modulating unit 140 executes multivalued modulation in the 8PSK shown in FIG. 2. Since the modulation scheme employed by the modulating unit 140 is the 8PSK, the mapping unit 130 executes labeling which splits the bit sequence interleaved by the interleaver 120 into three-bit bit sequences.

After that, the mapping unit 130 executes mapping which makes the three-bit bit sequences split by the labeling correspond to any signal point of the 8PSK in accordance with the contents of the bit sequences, and outputs a result of the mapping to the modulating unit 140. The modulating unit 140 processes a carrier by the multivalued modulation using the processing result of the mapping unit 130 and irradiates the carrier into space via an antenna.

The receiving apparatus 203 comprises a demodulating unit 210, a detecting unit 220, a deinterleaver 230, an LDPC decoding unit 240, a grouping unit 253 and a scheduling unit 263. The demodulating unit 210 receives the radio signal transmitted from the transmitting apparatus 100 via an antenna and demodulates the received signal in the 8PSK.

The detecting unit 220 detects a demodulation result of the demodulating unit 210 and acquires a likelihood value of each bit in the bit sequence of the interleaved state. The likelihood value of each bit is deinterleaved by the deinterleaver 230 and output to the LDPC decoding unit 240. The deinterleaver 230 corresponds to the interleaving of the interleaver 120 of the transmitting apparatus 100.

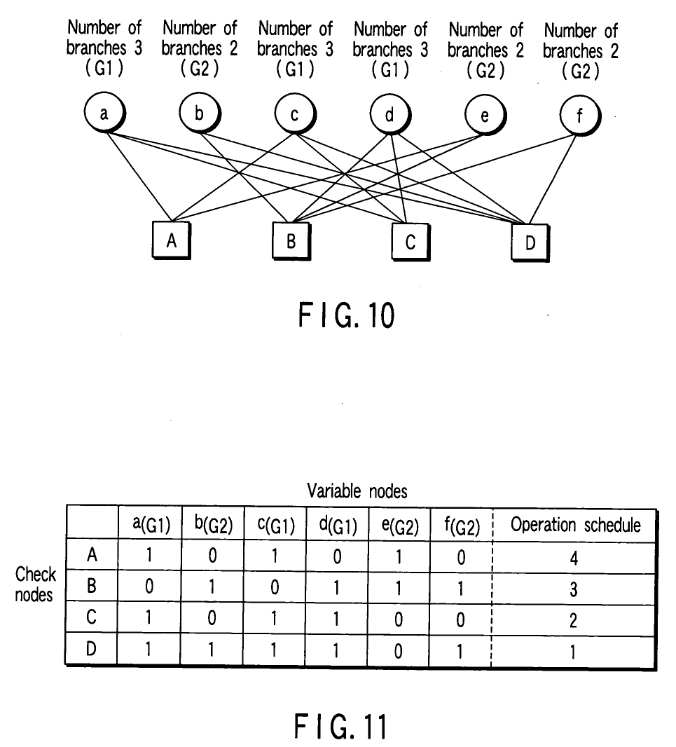

The grouping unit 253 groups variable nodes of the LDPC decoding unit 240 in accordance with the encoding of the LDPC encoding unit 110. The LDPC decoding unit 240 has a structure corresponding to the encoding of the LDPC encoding unit 110, and executes LDPC decoding by using variable nodes a, b, c, d, e, f and check nodes A, B, C, D. Correspondence of these nodes is determined on the basis of the decoding (encoding) algorithm. It is assumed here that the correspondence is determined as shown in FIG. 10.

In the structure of the check matrix of the LDPC, there are regular LDPC in which branches connected to all of the variable nodes are equal in number and non-regular LDPC in which branches connected to the variable nodes are different in number. In the non-regular LDPC, even if all of the variable nodes are equal in error probability at the modulation signal point, the error probability of each of the variable nodes is varied in accordance with the number of branches connected to each of the variable nodes.

The grouping unit 253 groups the variable nodes of the LDPC decoding unit 240 in accordance with the number of branches connected to the check nodes A, B, C, D. In FIG. 10, since the number of branches of the variable nodes a, c, d is “3”, the grouping unit 253 classifies the variable nodes a, c, d into group G1. Similarly, since the number of branches of the variable nodes b, e, f is “2”, the grouping unit 253 classifies the variable nodes b, e, f into group G2.

The scheduling unit 263 draws up an operation schedule to execute an operation of the check node using many variable nodes having more branches, with priority, on the basis of the result of grouping executed by the grouping unit 253 and the correspondence between the variable nodes and the check nodes shown in FIG. 10.

The variable nodes and the check nodes of the LDPC decoding unit 240 correspond as shown in FIG. 10. Thus, the scheduling unit 263 draws up the operation schedule as shown in FIG. 11. In this figure, “1” represents the correspondence between the variable nodes and the check nodes while “0” represents no correspondence there between.

In other words, the operation schedule of FIG. 11 is drawn, such that the check node corresponding to many variable nodes of group G2 retaining the likelihood values of higher reliabilities is calculated with priority while the check node corresponding to many variable nodes of group G1 retaining the likelihood values of lower reliabilities is calculated without priority.

The LDPC decoding unit 240 executes an LDPC decoding operation using the variable nodes and check nodes on the basis of the operation schedule drawn up by the scheduling unit 263. Thus, the LDPC decoding unit 240 acquires probability values of the respective bits of the receive data, executes hard decision about the acquired probability values and obtains the receive data. The LDPC decoding operation is explained below with reference to the operation schedule of FIG. 11.

By using the check node D which is the first place in the order of the operation schedule, the LDPC decoding unit 240 executes the operation on the basis of the likelihood values retained by the variable nodes a, b, c, d, f corresponding to the check node, and the operation result is retained by the check node D. By using the variable nodes a, b, c, d, f concerning the check node D, the LDPC decoding unit 240 executes the operation on the basis of likelihood values retained by the check nodes corresponding to each of the variable nodes, and updates the likelihood values retained by the variable nodes a, b, c, d, f on the basis of the operation result.

After that, by using the check node C which is the second place in the order of the operation schedule, the LDPC decoding unit 240 executes the operation on the basis of the likelihood values retained by the variable nodes a, c, d corresponding to the check node, and the operation result is retained by the check node C. By using the variable nodes a, c, d concerning the check node C, the LDPC decoding unit 240 executes the operation on the basis of likelihood values retained by the check nodes corresponding to each of the variable nodes, and updates the likelihood values retained by the variable nodes a, c, d on the basis of the operation result.

After that, by using the check node B which is the third place in the order of the operation schedule, the LDPC decoding unit 240 executes the operation on the basis of the likelihood values retained by the variable nodes b, d, e, f corresponding to the check node, and the operation result is retained by the check node B. By using the variable nodes b, d, e, f concerning the check node B, the LDPC decoding unit 240 executes the operation on the basis of likelihood values retained by the check nodes corresponding to each of the variable nodes, and updates the likelihood values retained by the variable nodes b, d, e, f on the basis of the operation result.

Finally, by using the check node A which is the fourth place in the order of the operation schedule, the LDPC decoding unit 240 executes the operation on the basis of the likelihood values retained by the variable nodes a, c, e corresponding to the check node, and the operation result is retained by the check node A. By using the variable nodes a, c, e concerning the check node A, the LDPC decoding unit 240 executes the operation on the basis of likelihood values retained by the check nodes corresponding to each of the variable nodes, and updates the likelihood values retained by the variable nodes a, c, e on the basis of the operation result.

The LDPC decoding unit 240, for example, repeats the LDPC decoding operation based on the above-described operation schedule at a preset number of times, recognizes the likelihood values finally retained by the variable nodes a, b, c, d, e, f as posteriori probability values, executes hard decision of the posteriori probability values and acquires the receive data. Besides setting the number of times of the repeated operation, the repeated operation may be stopped when the parity of the operation result is checked and a syndrome becomes “0”.

In addition, to detect the reliability of the likelihood of each variable node at the start of decoding, the LDPC decoding unit 240 may have a further step of executing an operation based on the likelihood values retained by the variable nodes a, b, c, d, e, f by using all of the check nodes A, B, C, D, making the check nodes A, B, C, D retain the operation result, using all of the variable nodes a, b, c, d, e, f and executing an operation based on the likelihood values of the check nodes corresponding to each of the variable nodes, and updating the likelihood values retained by the variable nodes a, b, c, d, e, f on the basis of the operation result.

In the receiving apparatus 203 having the above-described structure, it is noticed that the reliabilities of the likelihood values obtained on the basis of the variable nodes are different in accordance with the number of branches of the variable nodes of the LDPC decoding unit 240. The grouping unit 253 classifies the variable nodes of the LDPC decoding unit 240 into groups in accordance with the reliabilities.

The scheduling unit 263 preliminarily draws up an operation schedule to execute an operation of the check node using many variable nodes of higher reliabilities, with priority, on the basis of the result of grouping executed by the grouping unit 253 and the correspondence between the variable nodes and the check nodes used in the LDPC decoding operation of the LDPC decoding unit 240. The LDPC decoding unit 240 executes the LDPC decoding operation on the basis of the operation schedule.

According to the receiving apparatus 203 having the above-described structure, an operation of the check node using many variable nodes of higher reliabilities that have more branches, of the LDPC decoding operation, is executed with priority. The posteriori probability values can be therefore converged quickly during the repeated operation using the variable nodes and the check nodes. For this reason, even if the multivalued modulation is employed as the modulation scheme, the posteriori probability values can be efficiently converged without degrading the decoding characteristics.

In the present embodiment, the scheduling unit 263 draws up an operation schedule to execute an operation of the check node using the variable nodes retaining the likelihood values of higher reliabilities, with priority, on the basis of the result of grouping executed by the grouping unit 253 and the correspondence between the variable nodes and the check nodes used in the LDPC decoding operation of the LDPC decoding unit 240.

On the other hand, the grouping and the correspondence of the nodes have been known prior to executing the communications. Therefore, even if the receiving apparatus 203 does not comprise the grouping unit 253 and the scheduling unit 263, the preliminarily drawn operation schedule can be set in the LDPC decoding unit 240. On the basis of the grouping and the correspondence of the nodes, the operation schedule can be dynamically changed by the grouping unit 253 and the scheduling unit 263.

In addition, the scheduling unit 263 draws up the operation schedule of the check nodes and the LDPC decoding unit 240 executes the LDPC decoding operation on the basis of the operation schedule, as shown in FIG. 11. Instead of this, for example, the scheduling unit 263 may draw up the operation schedule to execute the operation using the variable nodes of higher reliabilities that have more branches, with priority.

In the case of FIG. 10, for example, after the LDPC decoding operation using the variable nodes and the check nodes is executed, the operation using the variable nodes a, c, d of group G1 of higher reliabilities that have more branches is executed. On the basis of the operation result, the operation using the check nodes A, B, C, D is executed. After that, the operation using the variable nodes b, e, f of group G2 is executed and, on the basis of the operation result, the operation using the check nodes A, B, C, D is executed.

According to such an operation schedule, too, the posteriori probability values can be converged quickly during the repeated operation using the variable nodes and the check nodes. Even if the multivalued modulation is employed as the modulation scheme, the posteriori probability values can be efficiently converged without degrading the decoding characteristics.

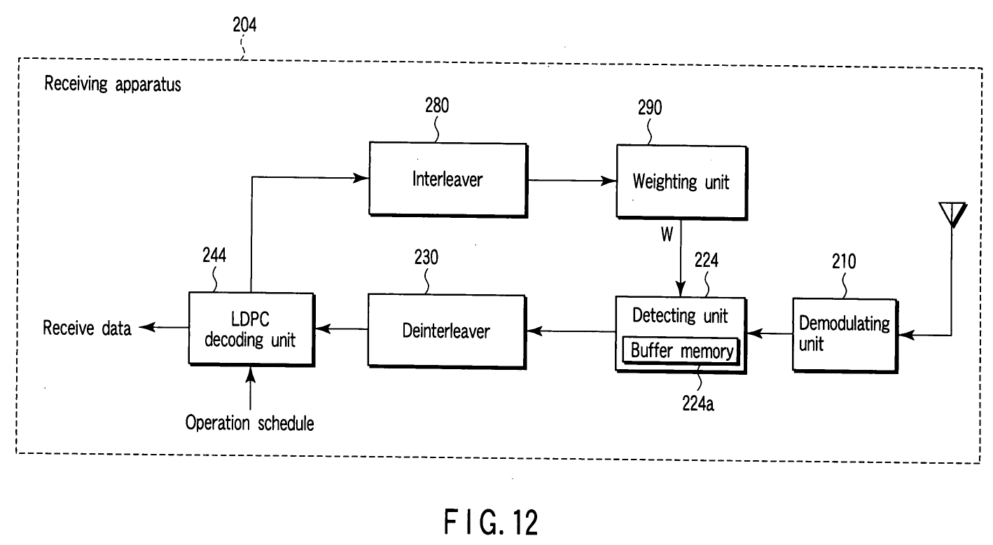

Next, a receiving apparatus 204 according to a fourth embodiment of the present invention will be explained. FIG. 12 shows a structure of the receiving apparatus. The receiving apparatus 204 receives the data transmitted from the transmitting apparatus 100 shown in FIG. 1, and decodes the data to acquire the receive data.

The receiving apparatus 204 comprises a demodulating unit 210, a detecting unit 224, a deinterleaver 230, an LDPC decoding unit 244, an interleaver 280 and a weighting unit 290. The demodulating unit 210 receives the radio signal transmitted from the transmitting apparatus 100 via an antenna and demodulates the received radio signal in the 8PSK.

The detecting unit 224 detects the demodulation result of the demodulating unit 210 and acquires the likelihood value of each bit in the bit sequence in the interleaved state. The likelihood value obtained at this time is temporarily stored in a buffer memory 224a provided in the detecting unit 224 as an initial likelihood value, and output to the deinterleaver 230.

After that, if a weighting factor W is provided to the detecting unit 224 by the weighting unit 290 which will be explained later, the detecting unit 224 multiplies the likelihood value of each bit stored in the buffer memory 224a, by the weighting factor W. The likelihood value thus multiplied by the weighting factor W is output to the deinterleaver 230. The detecting unit 224 adds identification information to identify initial likelihood values or corrected likelihood values, to the obtained likelihood value, and outputs the likelihood value to the deinterleaver 230.

The deinterleaver 230 deinterleaves each of the initial likelihood values and the corrected likelihood values which are input from the detecting unit 224 and outputs them to the detecting unit 224. The deinterleaver 230 corresponds to interleaving of the interleaver 120 of the transmitting apparatus 100.

The LDPC decoding unit 244 has a structure corresponding to the encoding of the LDPC encoding unit 110 of the transmitting apparatus 100, similarly to the LDPC decoding unit 240 in the first to third embodiments, and executes the LDPC decoding by using the variable nodes a, b, c, d, e, f and the check nodes A, B, C, D.

The LDPC decoding unit 244 executes an LDPC decoding operation using the variable nodes and check nodes on the basis of the operation schedule drawn up by a scheduling unit 261 or the like (not shown), and acquires probability values of the respective bits of the receive data. The schedule obtained by any one of the methods described in the first to third embodiment can be applied to the operation schedule used by the LDPC decoding unit 244.

The deinterleaver 230 has an equal structure to the interleaver 120 of the transmitting apparatus 100. The deinterleaver 230 interleaves the probability value input from the LDPC decoding unit 244 and outputs the interleaved probability value to the weighting unit 290, in the same steps as the interleaver 120.

On the basis of the probability value interleaved by the deinterleaver 230, the weighting unit 290 acquires the weighting factor W corresponding to each of the initial likelihood values stored in the buffer memory 224a of the detecting unit 224 and outputs the weighting factor W to the detecting unit 224. The weighting factor W is acquired here on the basis of the probability value, but can be obtained on the basis of a logarithmic likelihood value.

In the receiving apparatus 204 having the above-described structure, first, the detecting unit 224 temporarily stores the detection result in the buffer memory 224a as the initial likelihood values. On the basis of the probability value which the LDPC decoding unit 244 obtains on the basis of the initial likelihood values, the weighting unit 290 acquires the weighting factor W to correct the initial likelihood values.

After that, the detecting unit 224 corrects the initial likelihood values temporarily stored in the buffer memory 224a, with the weighting factor W. The LDPC decoding unit 244 acquires the probability value of the receive data on the basis of the corrected likelihood values of higher reliabilities, executes hard decision of the probability value and obtains the receive data.

Therefore, according to the receiving apparatus 204 having the above-described structure, the LDPC decoding operation is executed on the basis of the operation schedule, and the posteriori probability values are acquired from the likelihood values of higher reliabilities on which the LDPC decoding operation is reflected. The posteriori probability values can be therefore converged efficiently. For this reason, even if the multivalued modulation is employed as the modulation scheme, the posteriori probability values can be efficiently converged without degrading the decoding characteristics.

In the receiving apparatus 204 having the above-described structure, the LDPC decoding unit 244 acquires the initial probability values if the initial probability values are input. On the other hand, if the corrected probability values are input, the LDPC decoding unit 244 executes hard decision based on the probability values which are obtained by using the corrected probability values, and acquires the receive data.

In other words, the LDPC decoding unit 244 acquires the initial probability values and the receive data. However, the feature of acquiring the initial probability values and the feature of acquiring the receive data do not need to be combined, but the feature of acquiring the initial probability values and the feature of acquiring the receive data may be provided separately from each other.

In the above-described embodiments, the present invention is applied to the radio communications system. However, the present invention is not limited to the embodiments. The present invention can also be applied to various apparatus such as communications apparatus using cables, hard disk drives, audio apparatus and the like if they input, output and transfer the information by using the LDPC codes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A decoding apparatus of decoding encoded data with an LDPC code, the apparatus comprising:
detecting means for detecting an input signal including binary encoded data to acquire a likelihood value of each binary data item of a plurality of binary data items of the binary encoded data for obtaining a plurality of likelihood values which differ in reliability to one another;
schedule drawing means for drawing up an operation schedule to execute an arithmetic operation for decoding using with priority the likelihood value of higher reliability, in accordance with the reliability of the likelihood value of the each binary data item; and
decoding means for decoding the encoded data by executing the operation using the likelihood value acquired by the detecting means, in accordance with the operation schedule.

2. The decoding apparatus according to claim 1, further comprising demodulating means for demodulating a signal generated by multivalued modulation, the signal containing the binary data items assigned to a signal point, and
wherein the detecting means is adapted to detect an output of the demodulating means to acquire the likelihood values, the output corresponding to the input signal, and
in accordance with the reliability of each of the binary data items assigned to the signal point, the schedule drawing means is adapted to draw up the operation schedule using with priority the likelihood value of the binary data item corresponding to the higher reliability.

3. The decoding apparatus according to claim 2, wherein in accordance with the reliability of the likelihood value of each of the binary data items, the schedule drawing means is adapted to group the likelihood values into a plurality of likelihood value groups which differ in reliability to one another, and draw up the operation schedule using with priority the likelihood value included in one of the groups which has higher reliability.

4. The decoding apparatus according to claim 1, further comprising quality detection means for detecting quality of the input signal,
wherein the schedule drawing means is adapted to acquire the reliability of the likelihood value of the each binary data item, in accordance with the quality, and draw up the operation schedule using with priority the likelihood value of the higher reliability, in accordance with the acquired reliability.

5. The decoding apparatus according to claim 4, wherein the schedule drawing means is adapted to group the likelihood values into a plurality of likelihood groups which differ in reliability to one another, and draw up, in accordance with the reliability, the operation schedule using with priority the likelihood value included in one of the likelihood groups which has higher reliability.

6. The decoding apparatus according to claim 1, wherein the decoding means is adapted to include a plurality of variable nodes to which the likelihood values are assigned, and a plurality of check nodes that are made to correspond to the plurality of variable nodes in accordance with a decoding algorithm, and the decoding means is adapted to execute selectively a first operation in which each of the check nodes acquires a probability value by using the likelihood values assigned to the variable nodes, a second operation in which each of the variable nodes acquires a probability value by using the probability value acquired with corresponding ones of the check nodes, and a third operation in which each of the check nodes acquires probability value by using the probability value acquired with corresponding ones of the variable nodes, to obtain a probability value of each of the binary data items included in the data from the variable nodes, and
wherein the schedule drawing means draws up the operation schedule using with priority the check nodes more corresponding to the variable nodes.

7. The decoding apparatus according to claim 6, wherein the schedule drawing means is adapted to group the variable nodes into a plurality of variable node groups, in accordance with reliabilities of the assigned likelihood values and draw up the operation schedule using with priority the variable nodes included in one of the groups to which the likelihood value of the higher reliability is assigned.

8. A decoding apparatus of decoding encoded data with an LDPC code, the apparatus comprising:
detecting means for detecting an input signal including binary encoded data to acquire a likelihood value of each binary data item of a plurality of binary data items of the binary encoded data for obtaining a plurality of likelihood values which differ in reliability to one another;
memory means for storing the likelihood value;
schedule drawing means for drawing up an operation schedule to execute an arithmetic operation for decoding using with priority the likelihood value of higher reliability, in accordance with the reliability of the likelihood value of each of the binary data items;
probability operation means for acquiring a probability value of each of the binary data items, by executing the operation using the likelihood value, in accordance with the operation schedule;
weighting means for acquiring a weighting factor in accordance with the probability value;
multiplying means for multiplying the likelihood value stored in the storing means by the weighting factor; and
decoding means for decoding the encoded data by executing the operation using an output of the multiplying means, in accordance with the operation schedule.

9. A decoding circuit of decoding encoded data with an LDPC code, the circuit comprising:
detecting means for detecting an input signal including binary encoded data to acquire a likelihood value of each binary data item of a plurality of binary data items of the binary encoded data for obtaining a plurality of likelihood values which differ in reliability to one another;
schedule drawing means for drawing up an operation schedule to execute an arithmetic operation for decoding using with priority the likelihood value of higher reliability, in accordance with the reliability of the likelihood value of the each binary data item; and
decoding means for decoding the encoded data by executing the operation using the likelihood value acquired by the detecting means, in accordance with the operation schedule.

10. The decoding circuit according to claim 9, further comprising demodulating means for demodulating a signal generated by multivalued modulation, the signal containing the binary data items assigned to a signal point, and
wherein the detecting means is adapted to detect an output of the demodulating means to acquire the likelihood values, the output corresponding to the input signal, and
in accordance with the reliability of each of the binary data items assigned to the signal point, the schedule drawing means is adapted to draw up the operation schedule using with priority the likelihood value of the binary data item corresponding to the higher reliability.

11. The decoding circuit according to claim 10, wherein in accordance with the reliability of the likelihood value of each of the binary data items, the schedule drawing means is adapted to group the likelihood values into a plurality of likelihood value groups which differ in reliability to one another, and draw up the operation schedule using with priority the likelihood value included in one of the groups which has higher reliability.

12. The decoding circuit according to claim 9, further comprising quality detection means for detecting quality of the input signal,
wherein the schedule drawing means is adapted to acquire the reliability of the likelihood value of the each binary data item, in accordance with the quality, and draw up the operation schedule using with priority the likelihood value of the higher reliability, in accordance with the acquired reliability.

13. The decoding circuit according to claim 12, wherein the schedule drawing means is adapted to group the likelihood values into a plurality of likelihood groups which differ in reliability to one another, and draw up, in accordance with the reliability, the operation schedule using with priority the likelihood value included in one of the likelihood groups which has higher reliability.

14. The decoding circuit according to claim 9, wherein the decoding means is adapted to include a plurality of variable nodes to which the likelihood values are assigned, and a plurality of check nodes that are made to correspond to the plurality of variable nodes in accordance with a decoding algorithm, and the decoding means is adapted to execute selectively a first operation in which each of the check nodes acquires a probability value by using the likelihood values assigned to the variable nodes, a second operation in which each of the variable nodes acquires a probability value by using the probability value acquired with corresponding ones of the check nodes, and a third operation in which each of the check nodes acquires probability value by using the probability value acquired with corresponding ones of the variable nodes, to obtain a probability value of each of the binary data items included in the data from the variable nodes, and
wherein the schedule drawing means draws up the operation schedule using with priority the check nodes more corresponding to the variable nodes.

15. The decoding circuit according to claim 14, wherein the schedule drawing means is adapted to group the variable nodes into a plurality of variable node groups, in accordance with reliabilities of the assigned likelihood values and draw up the operation schedule using with priority the variable nodes included in one of the groups to which the likelihood value of the higher reliability is assigned.

16. A decoding circuit of decoding encoded data with an LDPC code, the circuit comprising:
detecting means for detecting an input signal including binary encoded data to acquire a likelihood value of each binary data item of a plurality of binary data items of the binary encoded data for obtaining a plurality of likelihood values which differ in reliability to one another;
memory means for storing the likelihood value;
schedule drawing means for drawing up an operation schedule to execute an arithmetic operation for decoding using with priority the likelihood value of higher reliability, in accordance with the reliability of the likelihood value of each of the binary data items;
probability operation means for acquiring a probability value of each of the binary data items, by executing the operation using the likelihood value, in accordance with the operation schedule;
weighting means for acquiring a weighting factor in accordance with the probability value;
multiplying means for multiplying the likelihood value stored in the storing means by the weighting factor; and
decoding means for decoding the encoded data by executing the operation using an output of the multiplying means, in accordance with the operation schedule.

17. A decoding apparatus of decoding encoded data with an LDPC code, the apparatus comprising:
a detecting unit configured to detect an input signal including binary encoded data to acquire a likelihood value of each binary data item of a plurality of binary data items of the binary encoded data for obtaining a plurality of likelihood values which differ in reliability to one another;
a schedule drawing unit configured to draw up an operation schedule to execute an arithmetic operation for decoding using with priority the likelihood value of higher reliability, in accordance with the reliability of the likelihood value of the each binary data item; and
a decoding unit configured to decode the encoded data by executing the operation using the likelihood value acquired by the detecting unit, in accordance with the operation schedule.

18. A decoding apparatus of decoding encoded data with an LDPC code, the apparatus comprising:
a detecting unit configured to detect an input signal including binary encoded data to acquire a likelihood value of each binary data item of a plurality of binary data items of the binary encoded data for obtaining a plurality of likelihood values which differ in reliability to one another;
a memory to store the likelihood value;
a schedule drawing unit configured to draw up an operation schedule to execute an arithmetic operation for decoding using with priority the likelihood value of higher reliability, in accordance with the reliability of the likelihood value of each of the binary data items;
a probability operation unit configured to acquire a probability value of each of the binary data items, by executing the operation using the likelihood value, in accordance with the operation schedule;
a weighting unit configured to acquire a weighting factor in accordance with the probability value;
a multiplying unit configured to multiply the likelihood value stored in the storing unit by the weighting factor; and
a decoding unit configured to decode the encoded data by executing the operation using an output of the multiplying unit, in accordance with the operation schedule.

19. A decoding circuit of decoding encoded data with an LDPC code, the circuit comprising:
a detecting unit configured to detect an input signal including binary encoded data to acquire a likelihood value of each binary data item of a plurality of binary data items of the binary encoded data for obtaining a plurality of likelihood values which differ in reliability to one another;
a schedule drawing unit configured to draw up an operation schedule to execute an arithmetic operation for decoding using with priority the likelihood value of higher reliability, in accordance with the reliability of the likelihood value of the each binary data item; and
a decoding unit configured to decode the encoded data by executing the operation using the likelihood value acquired by the detecting unit, in accordance with the operation schedule.

20. A decoding circuit of decoding encoded data with an LDPC code, the circuit comprising:
a detecting unit configured to detect an input signal including binary encoded data to acquire a likelihood value of each binary data item of a plurality of binary data items of the binary encoded data for obtaining a plurality of likelihood values which differ in reliability to one another;
a memory to store the likelihood value;
a schedule drawing unit configured to draw up an operation schedule to execute an arithmetic operation for decoding using with priority the likelihood value of higher reliability, in accordance with the reliability of the likelihood value of each of the binary data items;
a probability operation unit configured to acquire a probability value of each of the binary data items, by executing the operation using the likelihood value, in accordance with the operation schedule;
a weighting unit configured to acquire a weighting factor in accordance with the probability value;
a multiplying unit configured to multiply the likelihood value stored in the storing unit by the weighting factor; and
a decoding unit configured to decode the encoded data by executing the operation using an output of the multiplying unit, in accordance with the operation schedule.
